(19) United States
(12) Patent Application Publication
(10) Pub. No.: US 2024/0321975 A1
(43) Pub. Date: Sep. 26, 2024

(54) BIPOLAR TRANSISTOR AND SEMICONDUCTOR

(71) Applicant: Murata Manufacturing Co., Ltd., Kyoto-fu (JP)

(72) Inventors: Kenji SASAKI, Nagaokakyo-shi (JP); Koji INOUE, Nagaokakyo-shi (JP); Shinnosuke TAKAHASHI, Nagaokakyo-shi (JP); Satoshi GOTO, Nagaokakyo-shi (JP); Masao KONDO, Nagaokakyo-shi (JP)

(73) Assignee: Murata Manufacturing Co., Ltd., Kyoto-fu (JP)

(21) Appl. No.: 18/734,477

(22) Filed: Jun. 5, 2024

Related U.S. Application Data
(63) Continuation of application No. PCT/JP2022/039394, filed on Oct. 21, 2022.

(30) Foreign Application Priority Data
Dec. 17, 2021 (JP) 2021-205186

(51) Int. Cl. H01L 29/417; H01L 23/00; H01L 23/48; H01L 23/528; H01L 27/082; H01L 29/205; H01L 29/737

(52) U.S. Cl. CPC H01L 29/41708; H01L 23/481; H01L 23/5286; H01L 24/13; H01L 27/0823; H01L 29/205; H01L 29/7371; H01L 2224/13026; H01L 2924/10329; H01L 2924/10338; H01L 2924/13051

(57) ABSTRACT

A mesa structure including a collector layer, a base layer, and an emitter layer laminated on a substrate is formed. An emitter electrode electrically connected to the emitter layer is disposed on the mesa structure. Moreover, a base electrode electrically connected to the base layer is disposed on the mesa structure. A collector electrode is disposed in such a manner as to surround the mesa structure in plan view, and the collector electrode is electrically connected to the collector layer. The emitter electrode includes a first part and a second part. In plan view, the base electrode surrounds the first part of the emitter electrode, and the second part of the emitter electrode surrounds the base electrode.

### CROSS-REFERENCE TO RELATED APPLICATIONS

This application claims benefit of priority to International Patent Application No. PCT/JP2022/039394, filed Oct. 21, 2022, and to Japanese Patent Application No. 2021-205186, filed Dec. 17, 2021, the entire contents of each are incorporated herein by reference.

### BACKGROUND

### Technical Field

The present disclosure relates a bipolar transistor and a semiconductor device.

### Background Art

A heterojunction bipolar transistor (HBT) is used as a high-frequency amplifier device. An index which shows high-frequency characteristics of the HBT includes a maximum oscillation frequency fmax. The maximum oscillation frequency fmax is an index indicating an amplification factor of power. In order to increase the maximum oscillation frequency fmax, base resistance and base-collector junction capacitance are desirably reduced.

Japanese Unexamined Patent Application Publication (Translation of PCT Application) No. 2010-503999 discloses a bipolar transistor that includes two ring-shaped base terminals, a ring-shaped emitter terminal, and a ring-shaped collector terminal formed by diffusion regions. The emitter terminal is disposed between the inner-side base terminal and the outer-side base terminal. The collector terminal surrounds the outer-side base terminal.

### SUMMARY

In the bipolar transistor disclosed in Japanese Unexamined Patent Application Publication (Translation of PCT Application) No. 2010-503999, base-collector junction is formed in such a manner as to cover the two base terminals and the emitter terminal in plan view. An area of a base-collector junction interface is larger than an area obtained by adding areas of the two base terminals to an area of the emitter terminal. Since reducing base-collector junction capacitance is difficult, improving a maximum oscillation frequency fmax is also difficult.

Accordingly, the present disclosure provides a bipolar transistor capable of improving a maximum oscillation frequency fmax. Another object of the present disclosure is to provide a semiconductor device including the bipolar transistor.

According to an aspect of the present disclosure, there is provided a bipolar transistor including a substrate; a mesa structure including a collector layer, a base layer, and an emitter layer laminated on the substrate; an emitter electrode disposed on the mesa structure and electrically connected to the emitter layer; a base electrode disposed on the mesa structure and electrically connected to the base layer; and a collector electrode disposed in such a manner as to surround the mesa structure in plan view, and electrically connected to the collector layer. The emitter electrode includes a first part and a second part, and in plan view, the base electrode surrounds the first part of the emitter electrode, and the second part of the emitter electrode surrounds the base electrode.

According to another aspect of the present disclosure, there is provided a semiconductor device including a plurality of the bipolar transistors described above, in which the plurality of bipolar transistors are formed on the substrate in common, arranged in a staggered manner in plan view, and connected in parallel to one another.

By the base electrode and the emitter electrode being configured as described above, parasitic base resistance and base-collector junction capacitance can be reduced. As a result, the maximum oscillation frequency fmax can be improved.

### BRIEF DESCRIPTION OF THE DRAWINGS

FIG. 1 is a plan view of a bipolar transistor according to a first example;

FIGS. 2A and 2B are sectional views taken along a one-dot chain line 2A-2A and a one-dot chain line 2B-2B in FIG. 1, respectively;

FIG. 3A is a graph illustrating a measurement result of an attainment temperature of an HBT when direct current is flowed between an emitter and a collector of the HBT for a short period of time, and FIG. 3B is a plan view of a bipolar transistor according to a comparative example;

FIGS. 4A and 4B are plan views illustrating electrode arrangement in samples for which an SOA boundary is measured;

FIGS. 5A and 5B are graphs showing a relative value of a collector voltage at which the SOA boundary of the bipolar transistor illustrated in FIGS. 4A and 4B sharply falls;

FIG. 6 is a graph showing a measurement result of I-V characteristics of the bipolar transistor;

FIG. 7 is a graph showing a measurement result of base resistance of the bipolar transistor illustrated in FIGS. 4A and 4B;

FIG. 8 is a graph showing a measurement result of a maximum stable power gain (MSG) and a maximum available power gain (MAG) of the bipolar transistor;

FIGS. 9A and 9B are plan views illustrating shapes and arrangement of a base electrode and an emitter electrode in a bipolar transistor according to a modification of the first example;

FIG. 10 is a plan view of a bipolar transistor according to another modification of the first example;

FIG. 11A is a plan view of a bipolar transistor according to still another modification of the first example, and FIG. 11B is a sectional view taken along a one-dot chain line 11B-11B in FIG. 11A;

FIG. 12 is an equivalent circuit diagram of a semiconductor device according to a second example;

FIG. 13 is a plan view illustrating a planar arrangement of respective components of the semiconductor device according to the second example;

FIG. 14 is a sectional view taken along a one-dot chain line 14-14 in FIG. 13;

FIG. 15 is a plan view illustrating a planar arrangement of respective components of a semiconductor device according to a modification of the second example;

FIG. 16 is a plan view illustrating a planar arrangement of respective components of a semiconductor device according to a third example;

FIG. 17 is a sectional view taken along a one-dot chain line 17-17 in FIG. 16;

FIG. 18 is a block diagram of a semiconductor device according to a fourth example;

FIG. 19 is a view illustrating arrangement of respective components in a substrate of the semiconductor device according to the fourth example; and

FIG. 20 is a schematic sectional view in a state in which the semiconductor device according to the fourth example is mounted on a module board.

### DETAILED DESCRIPTION

### First Example

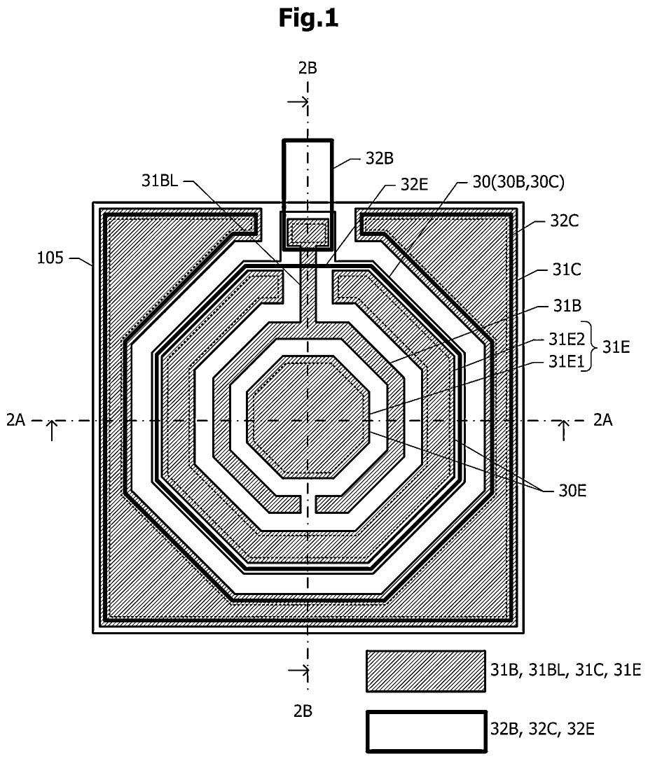

A bipolar transistor according to a first example is described with reference to the drawings from FIGS. 1 to 8.

FIG. 1 is a plan view of the bipolar transistor according to the first example. At an inner side of a subcollector layer 105 which is made from an n-type semiconductor formed on a substrate, a mesa structure 30 is disposed. The mesa structure 30 includes a collector layer 30C, a base layer 30B, and an emitter layer 30E laminated in this order from a substrate side. Shapes of the collector layer 30C and the base layer 30B substantially match one another in plan view, including a regular octagon part and a projecting part projecting from one side of the regular octagon. The emitter layer 30E is disposed at an inner side of the collector layer 30C and the base layer 30B in plan view.

When seen in plan view, an emitter electrode 31E, a base electrode 31B, and a base electrode extended part 31BL are disposed at an inner side of the mesa structure 30. A collector electrode 31C is disposed at an inner side of the subcollector layer 105 and an outer side of the mesa structure 30. In FIG. 1, hatching is applied to the base electrode 31B, the base electrode extended part 31BL, the collector electrode 31C, and the emitter electrode 31E. The emitter electrode 31E is electrically connected to the emitter layer 30E, and the base electrode 31B is electrically connected to the base layer 30B. The collector electrode 31C is electrically connected to the collector layer 30C with the subcollector layer 105 interposed therebetween.

The emitter electrode 31E includes a first part 31E1 and a second part 31E2. The emitter layer 30E is disposed in such a manner as to substantially overlap with the first part 31E1 and the second part 31E2 in plan view. The first part 31E1 is disposed at a center part of the regular octagon part of the mesa structure 30 in plan view, and the entire area inside a perimeter of the first part 31E1 is the first part 31E1 of the emitter electrode 31E. In other words, the first part 31E1 does not have a hollow shape, but has a solid shape in plan view. As one example, the first part 31E1 has a shape corresponding to a reduced shape of the regular octagon part of the mesa structure 30 with its center position fixed.

The base electrode 31B surrounds the first part 31E1 of the emitter electrode 31E in plan view. More specifically, the base electrode 31B has a common center with the first part 31E1, and is disposed along a perimeter of a regular octagon which is slightly larger than the first part 31E1. The base electrode 31B has one gap. This gap is provided at a part corresponding to a middle point of a side positioned farthest from the projecting part of the mesa structure 30.

The second part 31E2 of the emitter electrode 31E surrounds the base electrode 31B in plan view. More specifically, the second part 31E2 has a common center with the first part 31E1, and is disposed along a perimeter of a regular octagon which covers the base electrode 31B. The second part 31E2 has one gap. This gap is provided at a part corresponding to a middle point of a side positioned closest to the projecting part of the mesa structure 30.

The base electrode extended part 31BL extends from the base electrode 31B to an outer side of the second part 31E2 of the emitter electrode 31E while passing through the gap of the second part 31E2. A tip end of the base electrode extended part 31BL is widened, and is disposed within the projecting part of the mesa structure 30 in plan view.

The collector electrode 31C surrounds the second part 31E2 of the emitter electrode 31E in plan view. More specifically, an inner-peripheral edge of the collector electrode 31C has a shape along a perimeter of a regular octagon which covers the regular octagon part of the mesa structure 30. The collector electrode 31C has one gap. The tip end of the base electrode extended part 31BL is disposed in the gap.

Emitter wiring 32E, base wiring 32B, and collector wiring 32C are disposed on the emitter electrode 31E, the base electrode 31B, and the collector electrode 31C with an interlayer dielectric interposed therebetween. In FIG. 1, the emitter wiring 32E, the base wiring 32B, and the collector wiring 32C are indicated by relatively thick outlines compared to other components.

An edge of the emitter wiring 32E substantially matches an outer-peripheral edge of the second part 31E2 of the emitter electrode 31E. A shape of the emitter wiring 32E in plan view is a regular octagon having a common center with the first part 31E1 of the emitter electrode 31E, and the entire area inside a perimeter of the regular octagon is the emitter wiring 32E. The emitter wiring 32E is connected to the first part 31E1 and the second part 31E2 of the emitter electrode 31E through a cavity provided to the interlayer dielectric below the emitter wiring 32E. In FIG. 1, the cavity for connecting the emitter wiring 32E to the first part 31E1 and the second part 31E2 of the emitter electrode 31E is indicated by a broken line.

The base wiring 32B is extended to an outer side of the subcollector layer 105 from a portion overlapping with the tip end of the base electrode extended part 31BL. The base wiring 32B is connected to the tip end of the base electrode extended part 31BL. In FIG. 1, a cavity for connecting the base wiring 32B to the tip end of the base electrode extended part 31BL is indicated by a broken line.

The collector wiring 32C is disposed in such a manner as to overlap with the collector electrode 31C, and is connected to the collector electrode 31C. In FIG. 1, a cavity for connecting the collector wiring 32C to the collector electrode 31C is indicated by a broken line.

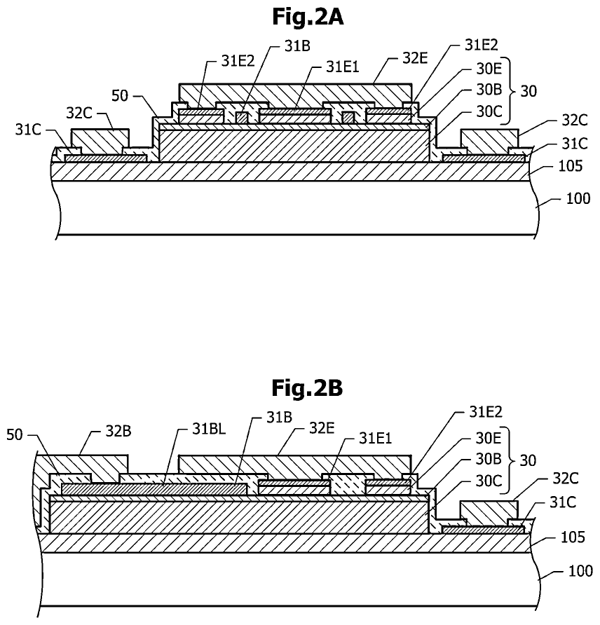

FIGS. 2A and 2B are sectional views taken along a one-dot chain line 2A-2A and a one-dot chain line 2B-2B in FIG. 1, respectively. The subcollector layer 105 is disposed on a partial range of a substrate 100. FIGS. 2A and 2B illustrate the range where the subcollector layer 105 is disposed. The mesa structure 30 is formed on a partial range of the subcollector layer 105. The mesa structure 30 includes a part in a first step including the collector layer 30C and the base layer 30B, and a part in a second step including the emitter layer 30E.

An edge of the collector layer 30C substantially matches an edge of the base layer 30B. The emitter layer 30E is disposed immediately below each of the first part 31E1 and the second part 31E2 (FIG. 1) of the emitter electrode 31E. The emitter electrode 31E is electrically connected to the emitter layer 30E. The base electrode 31B is formed on the base layer 30B. The base electrode 31B is electrically connected to the base layer 30B. Note that a ledge structure in which an emitter ledge layer is disposed on the base layer 30B may be adopted. In this case, the base electrode 31B is electrically connected to the base layer 30B with an alloyed region penetrating the emitter ledge layer being interposed therebetween.

The base electrode extended part 31BL continues to the base electrode 31B. The base electrode extended part 31BL is also connected to the base layer 30B.

The collector electrode 31C is disposed at a range of an upper surface of the subcollector layer 105, where the mesa structure 30 is not disposed. The collector electrode 31C is electrically connected to the collector layer 30C with the subcollector layer 105 interposed therebetween.

An interlayer dielectric 50 is disposed on the substrate 100 in such a manner as to cover the emitter electrode 31E, the base electrode 31B, the base electrode extended part 31BL, and the collector electrode 31C. The emitter wiring 32E, the base wiring 32B, and the collector wiring 32C of the first layer are disposed on the interlayer dielectric 50. The emitter wiring 32E is connected to the emitter electrode 31E through the cavity provided to the interlayer dielectric 50. The base wiring 32B is connected to the base electrode extended part 31BL through the cavity provided to the interlayer dielectric 50. The collector wiring 32C is connected to the collector electrode 31C through the cavity provided to the interlayer dielectric 50.

One example of a material of each semiconductor layer is described below. As the substrate 100, a semi-insulating GaAs substrate is used. The subcollector layer 105 and the collector layer 30C are made from n-type GaAs. The base layer 30B is made from p-type GaAs. The emitter layer 30E is made from n-type InGaP. The collector layer 30C, the base layer 30B, and the emitter layer 30E constitute a heterojunction bipolar transistor (HBT). Note that the collector layer 30C, the base layer 30B, and the emitter layer 30E may be made from another compound semiconductor.

Next, beneficial effects of the first example are described.

In the HBT, base current flows from the base electrode 31B to the emitter layer 30E via the base layer 30B. In order to reduce parasitic base resistance, a range where the base current flows may have a larger cross-sectional area orthogonal to a current direction. That is, in plan view illustrated in FIG. 1, a length of a part where the base electrode 31B and the emitter electrode 31E are opposed to one another (base-emitter opposed length) may be increased. Note that when an area of a base-collector junction interface increases as a result of increase in the base-emitter opposed length, base-collector junction capacitance increases. Therefore, the base-emitter opposed length is desirably increased without increase in the area of the base-collector junction interface.

In the first example, the first part 31E1 and the second part 31E2 of the emitter electrode 31E are respectively disposed on the inner side and outer side of the ring-shaped base electrode 31B with the gap. In other words, the edge of the base electrode 31B is opposed to the emitter electrode 31E over the substantially entire length of the base electrode 31B. Therefore, the portion where the base electrode 31B and the emitter electrode 31E are opposed to each other is lengthened, and a beneficial effect for reducing parasitic base resistance is obtained.

In plan view, base current flows between the opposed edges of the base electrode 31B and emitter electrode 31E. In the first example, substantially the entire range of the edge of the base electrode 31B is utilized effectively as a start point of the base current. That is, there are few parts not functioning as the start point of the base current. In other words, it can be said that the base electrode 31B has few unnecessary parts which substantially do not function as the base electrode.

As one comparative example, a configuration is considered in which a first base electrode is disposed at a center, an emitter electrode surrounds the first base electrode, a second base electrode surrounds the emitter electrode, and a collector electrode is disposed at the outermost periphery. In this comparative example, a perimeter of the second base electrode is opposed to the collector electrode, and is not opposed to the emitter electrode. That is, the part of the second base electrode on the perimeter does not function as a start point of base current. Therefore, it can be said that a range of the second base electrode at the outer-peripheral side is an unnecessary part which substantially does not function as the base electrode.

In plan view, the base-corrector junction interface substantially matches the mesa structure 30. That is, in plan view, the base-corrector junction interface covers the base electrode 31B. In the first example, since the base electrode 31B has few unnecessary parts, an area of the base-corrector junction interface can be reduced. Therefore, a beneficial effect for reducing base-collector junction capacitance is obtained.

Since the parasitic base resistance and the base-collector junction capacitance are reduced, a beneficial effect for improving a maximum oscillation frequency fmax of the HBT is obtained. In order to obtain a sufficient effect for improving the maximum oscillation frequency fmax, dimensions of the gap of the base electrode 31B and the gap of the second part 31E2 of the emitter electrode 31E in the circumferential direction are preferably made as small as possible.

The base electrode 31B is provided with the gap so as to allow application of a manufacturing process in which a completely closed ring-shaped pattern is not formable. Therefore, the gap of the base electrode 31B is preferably set to a minimum dimension allowable in an adopted manufacturing process. The second part 31E2 of the emitter electrode 31E is provided with the gap so as to extend the base electrode extended part 31BL from the inner side to the outer side of second part 31E2. Therefore, the dimension of the gap of the second part 31E2 of the emitter electrode 31E is preferably made to a size obtained by adding a positioning margin to a width of the base electrode extended part 31BL.

More generally, the gap of the base electrode 31B and the gap of the second part 31E2 of the emitter electrode 31E are preferably made smaller than a range which is assumed to be cutout by a sector shape fanned from a geometric center of the first part 31E1 of the emitter electrode 31E while having a center angle of 90°.

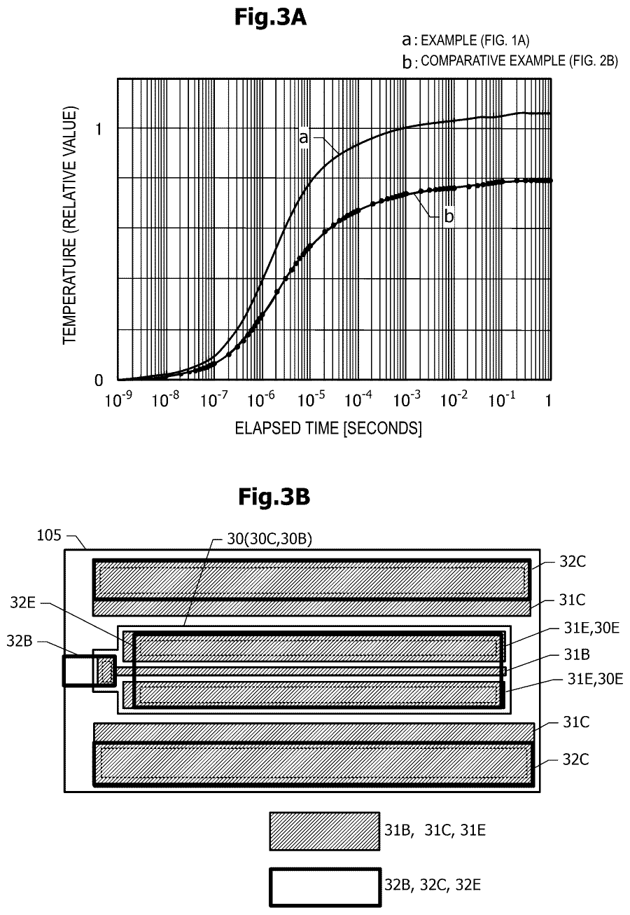

Next, an effect for improving breakdown withstand voltage of the bipolar transistor according to the first example is described with reference to FIGS. 3A and 3B.

HBTs are known to have reduced breakdown withstand voltage by impact ionization phenomenon becoming remarkable under a low-temperature condition. In other words, breakdown becomes less likely to occur when the HBT temperature rises. Increase in the temperature when large current near a breakdown boundary flows in the HBT acts in a direction to suppress the impact ionization phenomenon. Therefore, when the large current flows and the HBT temperature immediately increases, breakdown due to this large current becomes less likely to occur. Simulation results of temperature change in a bipolar transistor similar to the first example and a bipolar transistor according to a comparative example are described below.

As the bipolar transistor similar to the first example, a bipolar transistor in which the first part 31E1 of the emitter electrode 31E (FIG. 1) has a square shape and the second part 31E2 is not provided is used.

FIG. 3B is a plan view of the bipolar transistor according to the comparative example. The emitter electrode 31E is disposed on each of both sides of the base electrode 31B having an elongated shape. A shape of each emitter electrode 31E in plan view is an elongated rectangle with a length-to-width ratio of 3:40. The emitter wiring 32E is positioned from one emitter electrode 31E to the other emitter electrode 31E while intersecting with the base electrode 31B.

The collector electrode 31C is disposed on an outer side of each of the two emitter electrodes 31E. The collector wiring 32C is disposed in such a manner as to overlap with each collector electrode 31C. The base wiring 32B is connected to one end of the base electrode 31B. A coverage relationship, in plan view, of the subcollector layer 105, the collector layer 30C, the base layer 30B, and the emitter layer 30E is the same as the coverage relationship in the bipolar transistor according to the first example.

In the bipolar transistor similar to the first example, the length-to-width ratio of the emitter wiring 32E is substantially 1:1, whereas in the bipolar transistor according to the comparative example, the emitter wiring 32E has the elongated shape. Note that an area of the emitter layer 30E is the same in the bipolar transistor similar to the first example and the bipolar transistor according to the comparative example.

FIG. 3A is a graph illustrating a simulation result of an attainment temperature of an HBT when direct current is flowed between an emitter and a collector of the HBT for a short period of time. A horizontal axis indicates an elapsed time from a start of current supply in units of [seconds], and a vertical axis indicates an HBT temperature by a relative value. A curved line a on the graph shows temperature change of the bipolar transistor similar to the first example (FIG. 1), and a curved line b shows temperature change of the bipolar transistor according to the comparative example (FIG. 3B).

The temperature gets high in a shorter period in the bipolar transistor similar to the first example than in the bipolar transistor according to the comparative example. This is because the bipolar transistor similar to the first example has the shape with the length-to-width ratio of near 1:1 in plan view, and thus thermal diffusion in a substrate in-plane direction is less likely to occur. The bipolar transistor according to the first example also has the shape with the length-to-width ratio of near 1:1 in plan view, which is in common with the bipolar transistor similar to the first example. Therefore, also in the bipolar transistor according to the first example, the temperature gets high in a shorter period than in the bipolar transistor having the elongated shape.

In the bipolar transistor according to the first example, the temperature gets high in an extremely short period when large current flows, whereby a beneficial effect that breakdown is less likely to occur is obtained.

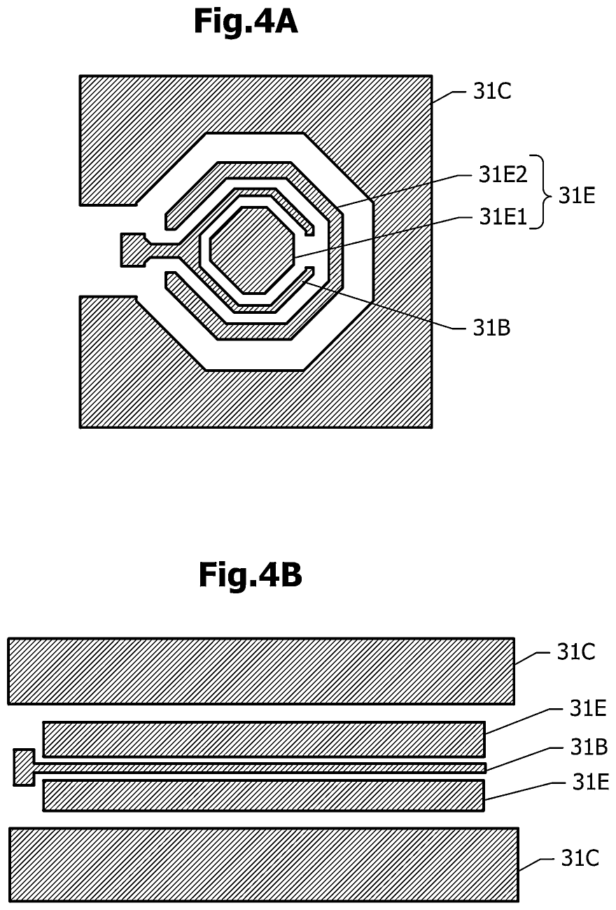

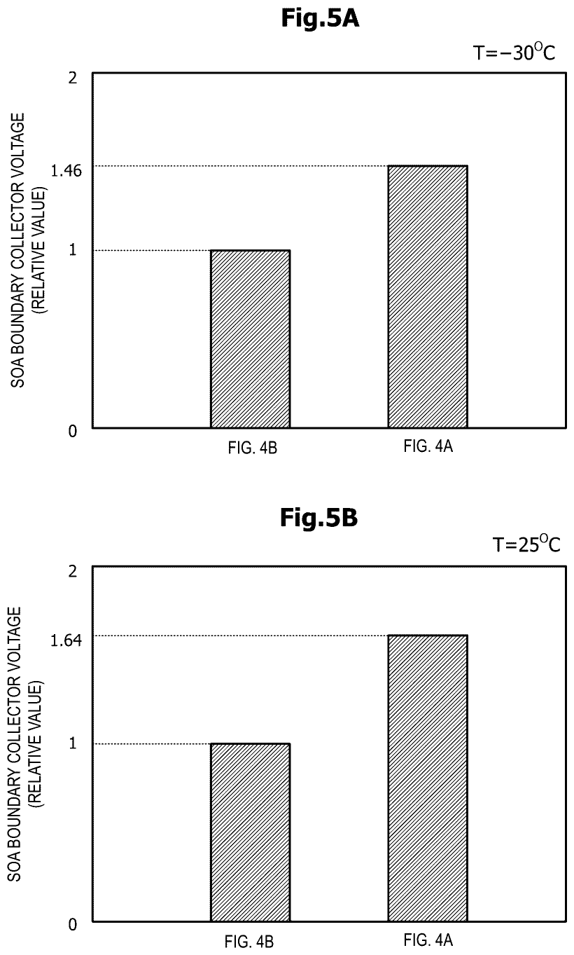

Next, measurement results of a safe operation area (SOA) for various bipolar transistors according to the first example and a comparative example are described with reference to the drawings from FIGS. 4A to 5B.

FIGS. 4A and 4B are plan views illustrating electrode arrangement in samples for which the SOA boundary is measured. FIG. 4A illustrates the electrode arrangement in the bipolar transistor according to the first example. That is, the emitter electrode 31E includes the first part 31E1 and the second part 31E2, and the base electrode 31B is disposed therebetween. The collector electrode 31C surrounds the second part 31E2 of the emitter electrode 31E.

FIG. 4B illustrates the electrode arrangement in the bipolar transistor according to the comparative example. The electrode arrangement in the bipolar transistor according to the comparative example illustrated in FIG. 4B is similar to the electrode arrangement in the bipolar transistor according to the comparative example illustrated in FIG. 3B. That is, the emitter electrode 31E is disposed on each of both sides of the base electrode 31B which is elongated in one direction, and the collector electrode 31C is disposed on an outer side of each emitter electrode 31E.

A total area of the emitter electrode 31E of the bipolar transistor is substantially equal in FIGS. 4A and 4B.

FIGS. 5A and 5B are graphs showing a relative value of a collector voltage at which the SOA boundary of the bipolar transistor illustrated in FIGS. 4A and 4B sharply falls. FIGS. 5A and 5B illustrate measurement results under conditions where a temperature T of the bipolar transistor is −30° C. and 25° C., respectively.

As illustrated in FIGS. 5A and 5B, under both of the low-temperature (T=−30° C.) and room-temperature (T=25° C.) conditions, a collector voltage at which an SOA boundary of the bipolar transistor according to the first example sharply falls is approximately 1.46 times that of the bipolar transistor according to the comparative example illustrated in FIG. 4B. As such, it can be seen that, in the bipolar transistor according to the first example, a beneficial effect for increasing the SOA is obtained.

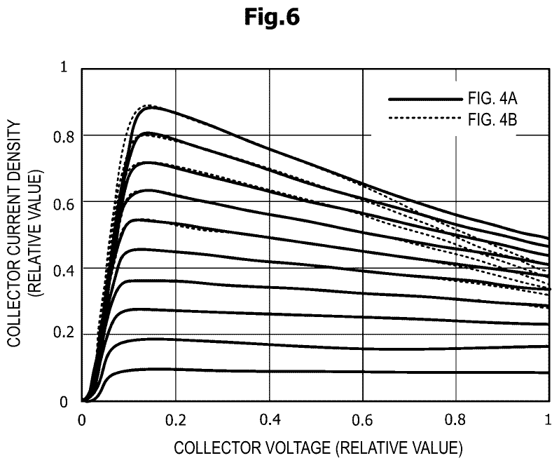

Next, a current collapse phenomenon is described with reference to FIG. 6.

FIG. 6 is a graph showing a measurement result of I-V characteristics of the bipolar transistor. A horizontal axis indicates a collector voltage by a relative value, and a vertical axis indicates a collector current density by a relative value. Solid lines and broken lines on the graph respectively show I-V characteristics of circuits in which multiple bipolar transistors illustrated in FIGS. 4A and 4B are arranged in a line to be connected in parallel to one another.

In the bipolar transistor having the elongated shape illustrated in FIG. 4B, as the collector voltage increases, the collector current decreases due to the current collapse phenomenon. On the other hand, in the bipolar transistor according to the first example illustrated in FIG. 4A, it can be seen that the current collapse phenomenon does not occur. As such, in the first example, a beneficial effect that the current collapse phenomenon is less likely to occur is obtained.

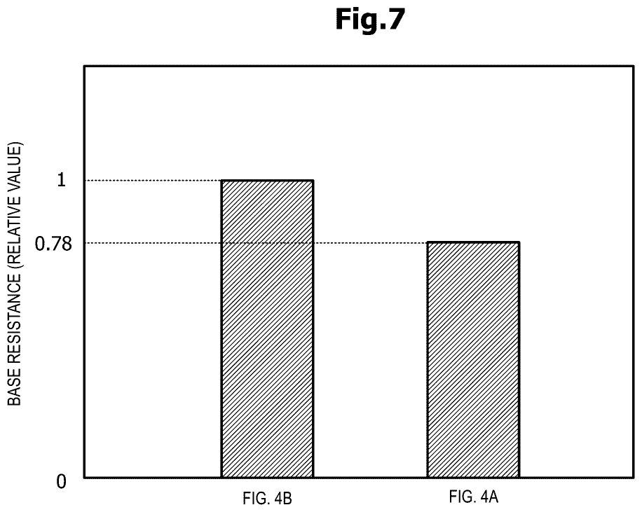

Next, base resistance is described with reference to FIG. 7.

FIG. 7 is a graph showing a measurement result of base resistance of the bipolar transistor illustrated in FIGS. 4A and 4B. The base resistance was measured at a frequency of 10 GHz. The base resistance in the bipolar transistor (FIG. 4A) according to the first example is reduced by approximately 22% compared to the base resistance in the bipolar transistor (FIG. 4B) according to the comparative example. As such, in the first example, a beneficial effect for reducing base resistance is obtained.

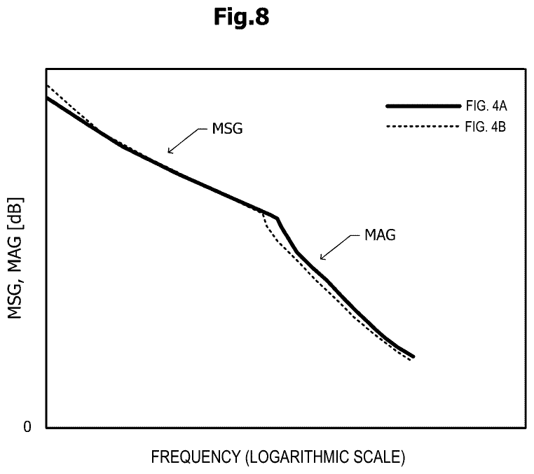

Next, the maximum oscillation frequency fmax is described with reference to FIG. 8.

FIG. 8 is a graph showing a measurement result of a maximum stable power gain (MSG) and a maximum available power gain (MAG) of the bipolar transistor. Horizontal axis indicates a frequency by a logarithmic scale, and a vertical axis indicates an MSG and an MAG in units [dB]. A frequency at which the MAG is 0 dB corresponds to the maximum oscillation frequency fmax. It can be seen that the MAG in the bipolar transistor (FIG. 4A) according to the first example is higher than the MAG in the bipolar transistor (FIG. 4B) according to the comparative example. Based on the measurement results illustrated in FIG. 8, it can be seen that, in the first example, a beneficial effect for improving the maximum oscillation frequency fmax is obtained.

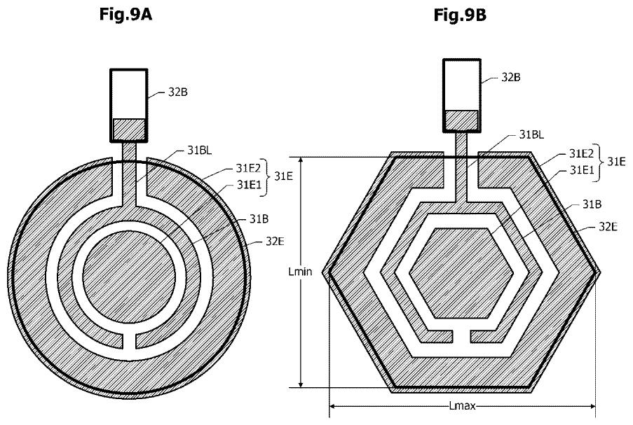

Next, a bipolar transistor according to a modification of the first example is described with reference to FIGS. 9A and 9B. FIGS. 9A and 9B are plan views illustrating shapes and arrangement of the base electrode 31B and the emitter electrode 31E in the bipolar transistor according to the modification of the first example.

In the first example (FIG. 1), the first part 31E1 of the emitter electrode 31E and the emitter wiring 32E have a regular octagonal shape in plan view. On the other hand, in the modification illustrated in FIG. 9A, the first part 31E1 of the emitter electrode 31E and the emitter wiring 32E have a circular shape in plan view. The base electrode 31B has a common center with the first part 31E1 of the emitter electrode 31E, and is disposed along a circumference covering the first part 31E1. The second part 31E2 of the emitter electrode 31E has a common center with the first part 31E1, and is disposed along a circumference covering the base electrode 31B. A shape of the emitter wiring 32E in plan view is a circle having a common center with the first part 31E1 of the emitter electrode 31E.

In the modification illustrated in FIG. 9B, the first part 31E1 of the emitter electrode 31E and the emitter wiring 32E have a regular hexagonal shape in plan view. Corresponding to this, the base electrode 31B and the second part 31E2 of the emitter electrode 31E have a shape along a perimeter of a regular hexagon.

In any of the first example (FIG. 1) and the modifications (FIGS. 9A and 9B) of the first example, the shape of the emitter wiring 32E in plan view has two line-symmetric axes orthogonal to one another. In the first example (FIG. 1) and the modification illustrated in FIG. 9A, a dimension of the emitter wiring 32E in a direction of one line-symmetric axis is equal to a dimension thereof in a direction of the other symmetric axis. That is, a length-to-width ratio of the shape of the emitter wiring 32E in plan view is 1:1.

In the modification illustrated in FIG. 9B, a dimension of the emitter wiring 32E in a direction of one line-symmetric axis is different from a dimension thereof in a direction of the other line-symmetric axis. The larger dimension is denoted by Lmax, and the smaller dimension is denoted by Lmin. Lmax/Lmin is approximately 1.15.

Like the comparative example illustrated in FIG. 3B, when the length-to-width ratio of the shape of the emitter wiring 32E in plan view largely deviates from 1:1, heat diffusion in an in-plane direction increases. Therefore, increase in the temperature after a start of current flow to the bipolar transistor becomes gradual. Sharp increase in the temperature after the start of current flow improves breakdown withstand voltage characteristics. Therefore, in order to improve the breakdown withstand voltage characteristics, the length-to-width ratio of the shape of the emitter wiring 32E in plan view is preferably made closer to 1:1. For example, Lmax/Lmin is preferably made 1.2 or less. As one example, when the emitter wiring 32E has a rectangular shape in plan view, a length of a long side is preferably made 1.2 times or less a length of a short side.

In the first example (FIG. 1), the first part 31E1 of the emitter electrode 31E and the emitter wiring 32E have a regular octagonal shape in plan view, whereas in the modification illustrated in FIG. 9B, the first part 31E1 of the emitter electrode 31E and the emitter wiring 32E have a regular hexagonal shape in plan view. As another modification, the first part 31E1 of the emitter electrode 31E and the emitter wiring 32E may have a regular polygonal shape with four or more vertexes. Alternatively, the shape may be a rectangular shape having a length of a long side 1.2 times or less a length of a short side.

These shapes of the electrode and wiring in plan view may be ones reflecting the shape of the mesa structure 30 (FIG. 1, FIG. 2A, FIG. 2B) in plan view. When the mesa structure 30 is formed by etching, the etching may be affected by a crystal plane orientation of the substrate 100 (FIG. 2A, FIG. 2B). The shape of the mesa structure 30 in plan view may be determined in consideration of the crystal plane orientation of the substrate 100. The shapes of the first part 31E1 of the emitter electrode 31E and the emitter wiring 32E may be determined in accordance with the shape of the mesa structure 30 determined in consideration of the crystal plane orientation of the substrate 100.

Next, beneficial effects of making the shapes of the emitter electrode 31E and the base electrode 31B in plan view in a regular polygon are described.

The emitter electrode 31E and the base electrode 31B (FIG. 1 or the like) are formed through different photolithography processes. Therefore, positioning error within an allowable range may be caused between the emitter electrode 31E and the base electrode 31B. When a part of the emitter electrode 31E gets closer to the base electrode 31B, an electric field concentrates at the part where the emitter electrode 31E and the base electrode 31B get closer to one another, which causes spatial variations in base current.

When positional deviation occurs in a case in which the emitter electrode 31E and the base electrode 31B have a regular polygonal shape in plan view, any of linear edges of the emitter electrode 31E gets closer to any of linear edges of the base electrode 31B. Since the edges both having linear shapes get closer to one another, an electric field does not concentrate at one point, and concentration of the electric field can be eased. Therefore, decrease in breakdown withstand voltage due to positional deviation can be suppressed.

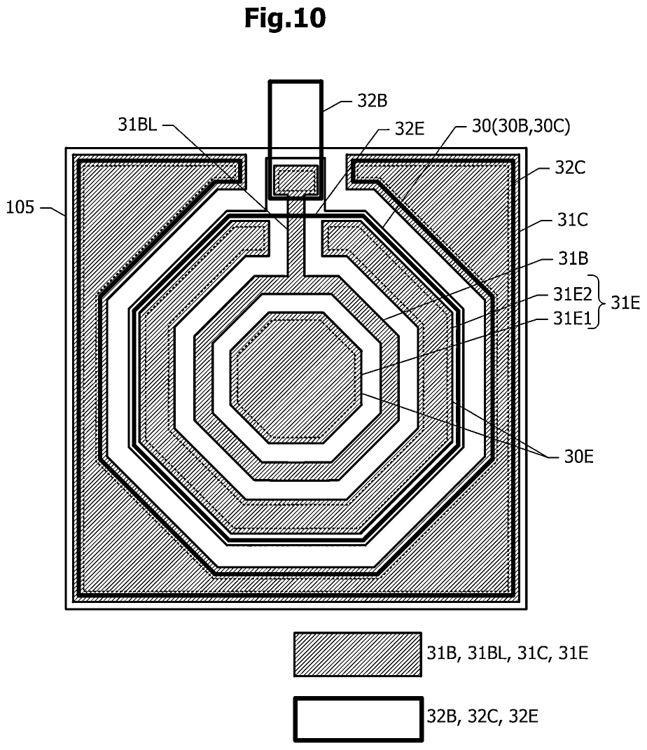

Next, a bipolar transistor according to another modification of the first example is described with reference to FIG. 10. FIG. 10 is a plan view of the bipolar transistor according to this modification. Also in FIG. 10, similar to FIG. 1, hatching is applied to the base electrode 31B, the base electrode extended part 31BL, the collector electrode 31C, and the emitter electrode 31E, and the base wiring 32B, the emitter wiring 32E, and the collector wiring 32C are indicated by relatively thick outlines.

In the first example (FIG. 1), the base electrode 31B has the gap, whereas in this modification, the base electrode 31B does not have a gap, and has a closed ring shape in plan view. In the first example, the base electrode 31B is provided with the gap so as to allow application of various manufacturing processes. In a case of adopting a manufacturing process capable of forming the base electrode 31B in a closed ring shape, the base electrode 31B is not necessarily formed with a gap. Also in the modifications of the first example illustrated in FIGS. 9A and 9B, similarly, the base electrode 31B may have a closed ring shape without a gap.

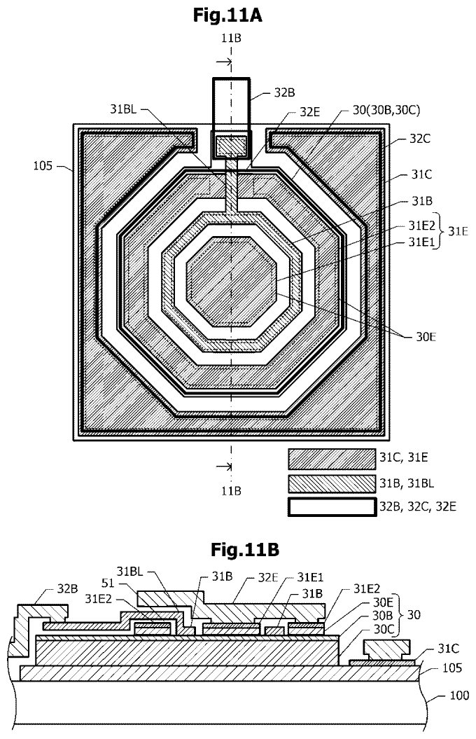

Next, a bipolar transistor according to still another modification of the first example is described with reference to FIGS. 11A and 11B. FIG. 11A is a plan view of the bipolar transistor according to this modification, and FIG. 11B is a sectional view taken along a one-dot chain line 11B-11B in FIG. 11A.

In FIG. 11A, the collector electrode 31C and the emitter electrode 31E are applied with relatively dark positively-sloped hatching, and the base electrode 31B and the base electrode extended part 31BL are applied with a relatively light negatively-sloped hatching. Similarly to FIG. 1, the base wiring 32B, the emitter wiring 32E, and the collector wiring 32C are indicated by relatively thick outlines.

In this modification, both of the base electrode 31B and the second part 31E2 of the emitter electrode 31E do not have a gap. The base electrode extended part 31BL intersects with the second part 31E2 of the emitter electrode 31E. An interlayer dielectric 51 (FIG. 11B) is disposed at the intersection part between the base electrode extended part 31BL and the second part 31E2, thus securing insulation therebetween. Moreover, the cavity for connecting the emitter wiring 32E to the emitter electrode 31E has a gap at a part where the base electrode extended part 31BL and the second part 31E2 intersect with one another. Like this modification, the second part 31E2 of the emitter electrode 31E may be configured without a gap.

Next, yet another modification of the first example is described. Although, in the first example (FIG. 1), the first part 31E1 of the emitter electrode 31E and the emitter wiring 32E have a regular octagonal shape in plan view, they may have a rounded regular octagonal shape with rounded corners. Similarly, in the modification illustrated in FIG. 9B, the first part 31E1 of the emitter electrode 31E and the emitter wiring 32E may have a rounded regular hexagonal shape in plan view. More generally, the first part 31E1 of the emitter electrode 31E and the emitter wiring 32E may have a rounded regular polygonal shape with four or more vertexes in plan view.

### Second Example

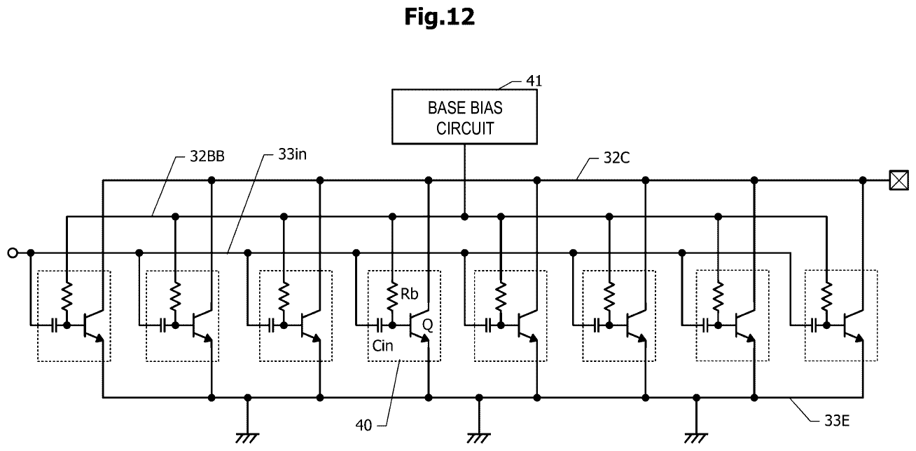

Next, a semiconductor device according to a second example is described with reference to FIGS. 12, 13, and 14. The semiconductor device according to the second example includes a plurality of bipolar transistors according to the first example or the modification thereof.

FIG. 12 is an equivalent circuit diagram of the semiconductor device according to the second example. The semiconductor device according to the second example includes multiple cells 40 connected in parallel to one another. Each of the multiple cells 40 includes a bipolar transistor Q, a base ballast resistor Rb, and an input capacitor Cin. Bases of the multiple bipolar transistors Q are connected to common signal input wiring 33 in with the corresponding input capacitors Cin interposed therebetween. A high-frequency signal is inputted into the base of the bipolar transistor Q through the signal input wiring 33 in and the input capacitor Cin.

Furthermore, the bases of the multiple bipolar transistors Q are connected to common base bias wiring 32BB with the corresponding base ballast resistors Rb interposed therebetween. Base bias is supplied from a base bias circuit 41 to the bipolar transistor Q through the base bias wiring 32BB and the base ballast resistor Rb.

Emitters of the multiple bipolar transistors Q are connected to a ground with common emitter wiring 33E interposed therebetween. Collectors of the multiple bipolar transistors Q are connected to the common collector wiring 32C. An output signal is outputted from the collectors of the multiple bipolar transistors Q through the collector wiring 32C.

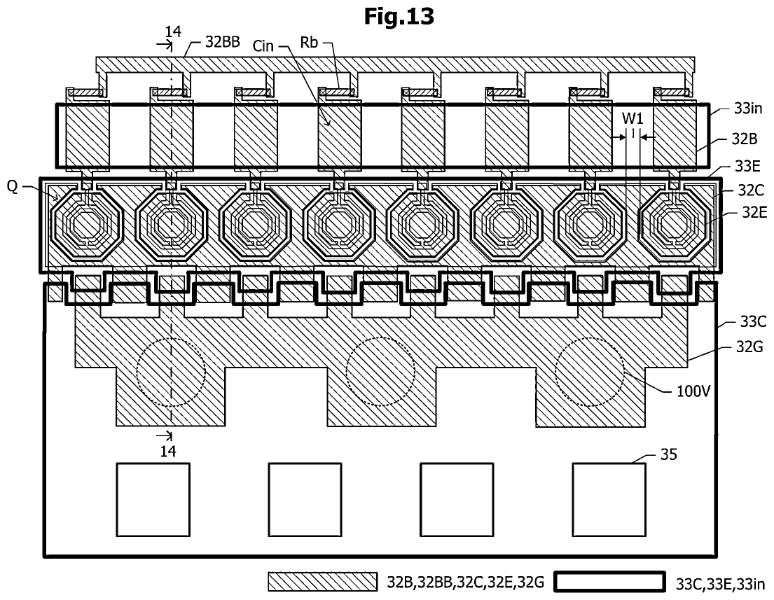

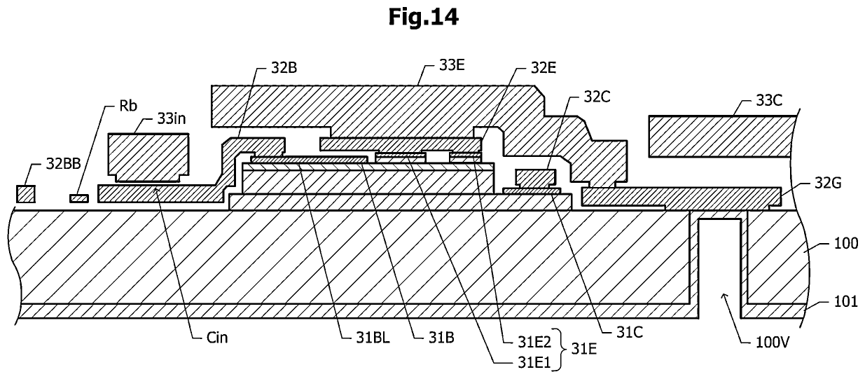

FIG. 13 is a plan view illustrating a planar arrangement of respective components of the semiconductor device according to the second example. FIG. 14 is a sectional view taken along a one-dot chain line 14-14 in FIG. 13. In FIG. 13, wiring of the first layer is applied with hatching, and wiring of the second layer is indicated by relatively thick outlines. In FIG. 14, illustration of an interlayer dielectric is omitted.

Multiple bipolar transistors Q, for example, eight bipolar transistors Q, are arranged in a line on a substrate in common. The signal input wiring 33 in is disposed on one side of the line in which the multiple bipolar transistors Q are aligned. The base wiring 32B is extended from each of the multiple bipolar transistors Q to the side where the signal input wiring 33 in is disposed. The base wiring 32B extends across the signal input wiring 33 in. The input capacitor Cin is formed at a part where each base wiring 32B intersects with the signal input wiring 33 in.

The base ballast resistor Rb is disposed in such a manner as to overlap with a tip end of each base wiring 32B. Each base ballast resistor Rb is connected to the common base bias wiring 32BB.

The emitter wiring 33E of the second layer is disposed in such as manner as to overlap with the multiple bipolar transistors Q. The emitter wiring 33E of the second layer is connected to the emitter wiring 32E of the first layer, the emitter wiring 32E of the first layer being disposed for each of the multiple bipolar transistors Q. On the opposite side from where the signal input wiring 33 in is disposed when seen from the line of the multiple bipolar transistors Q, ground wiring 32G of the first layer is disposed. A partial range of the emitter wiring 33E of the second layer overlaps with the ground wiring 32G, and the emitter wiring 33E is connected to the ground wiring 32G at the overlapping range.

In the first example (FIG. 1), one bipolar transistor and one piece of collector wiring 32C connected thereto are shown, whereas in this example, pieces of collector wiring 32C connected to the respective ones of multiple bipolar transistors Q continue to one another. A part of the collector wiring 32C passes between two pieces of emitter wiring 32E connected to the respective ones of two bipolar transistors Q adjacent to one another. A width of the part of the collector wiring 32C passing between the two pieces of emitter wiring 32E is denoted by W1.

A collector wiring 33C of the second layer is disposed in such a manner as to overlap with the ground wiring 32G of the first layer. A partial range of the collector wiring 33C of the second layer overlaps with the collector wiring 32C of the first layer, and the collector wiring 33C of the second layer is connected to the collector wiring 32C of the first layer at the overlapping range. Furthermore, the collector wiring 33C of the second layer is connected to a bonding pad 35.

A plurality of via holes 100V are formed at a range, overlapping with the ground wiring 32G, of the substrate 100. A back electrode 101 (FIG. 14) is formed on a back surface of the substrate 100. The back electrode 101 is connected to the ground wiring 32G through the via hole 100V.

The semiconductor device according to the second example is face-up mounted in a posture in which the back electrode 101 (FIG. 14) is facing toward a module board. The ground wiring 32G is connected to a ground terminal of the module board with the back electrode 101 (FIGS. 4A and 4B) in the via hole 100V interposed therebetween. The bonding pad 35 is provided on substrate 100, and the bonding pad 35 is connected to the collector wiring 33C.

The collector electrode 31C (FIG. 1) of each of the multiple bipolar transistors Q is connected to the bonding pad 35 with the collector wiring 32C of the first layer and the collector wiring 33C of the second layer interposed therebetween. The collector electrode 31C is connected to an outer terminal of the module board with a bonding wire connected to the bonding pad 35 interposed therebetween.

Next, beneficial effects of the second example are described.

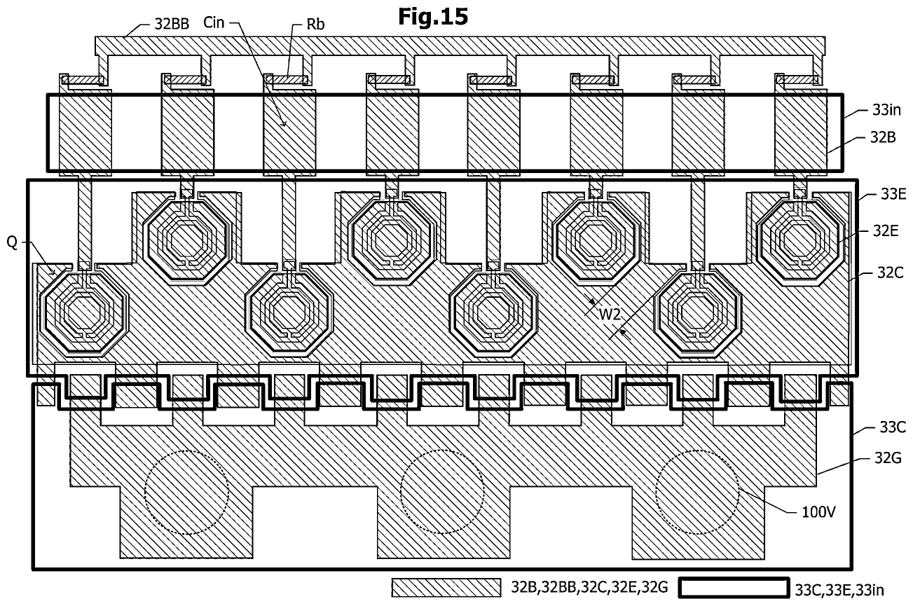

As the bipolar transistor Q included in the semiconductor device according to the second example, the bipolar transistor according to the first example or the modification thereof is used. Therefore, the beneficial effect for improving the maximum oscillation frequency fmax of the semiconductor device is obtained. Moreover, the beneficial effects for increasing the SOA as described with reference to FIGS. 5A and 5B and suppressing occurrence of the current collapse as described with reference to FIG. 6 are obtained. Next, a semiconductor device according to a modification of the second example is described with reference to FIG. 15.

FIG. 15 is a plan view illustrating a planar arrangement of respective components of the semiconductor device according to the modification of the second example. Also in FIG. 15, similarly to FIG. 13, wiring of the first layer is applied with hatching, and wiring of the second layer is indicated by relatively thick outlines. In FIG. 15, illustration of the bonding pad 35 (FIG. 13) is omitted.

In the second example (FIG. 13), the multiple bipolar transistors Q are arranged to be aligned linearly. On the other hand, in this modification, multiple bipolar transistors Q are arranged in a staggered manner. That is, when serial numbers are given to the multiple bipolar transistors Q from the bipolar transistor Q at one end to the bipolar transistor Q at the other end in the array direction, the bipolar transistors Q with an odd number and the bipolar transistors Q with an even number are disposed to be shifted in a direction orthogonal to the array direction.

When focusing on the respective ones of multiple bipolar transistors Q, the bipolar transistors Q closest to one another are arranged obliquely with respect to the array direction while having a gap therebetween. A part of the collector wiring 32C passes between two pieces of emitter wiring 32E connected to the respective two of bipolar transistors Q obliquely adjacent to one another. A width of the part of the collector wiring 32C passing between the two pieces of emitter wiring 32E is denoted by W2.

Next, beneficial effects of the modification of the second example illustrated in FIG. 15 are described.

When a pitch of the multiple bipolar transistors Q in the array direction is the same in the semiconductor device according to the second example (FIG. 13) and the semiconductor device according to the modification illustrated in FIG. 15, the width W2 (FIG. 15) of the collector wiring 32C can be made larger than the width W1 (FIG. 13). Widening the collector wiring 32C can reduce parasitic resistance of the collector wiring 32C.

Moreover, in the modification illustrated in FIG. 15, the gap between the two bipolar transistors Q closest to one another is wider than that in the second example (FIG. 13). Therefore, heat dissipation characteristics improve, and increase in temperature of the semiconductor device as a whole including the plurality of bipolar transistors Q can be suppressed.

Note that although increase in the temperature of the semiconductor device as a whole is suppressed, increase in temperature of each bipolar transistor Q in extremely short period, which is described with reference to FIG. 3A, is not affected by the pitch of the bipolar transistors Q. Therefore, also in the modification illustrated in FIG. 15, the beneficial effect for improving breakdown withstand voltage attributed to the increase in temperature in an extremely short period when large current flows is obtained.

### Third Example

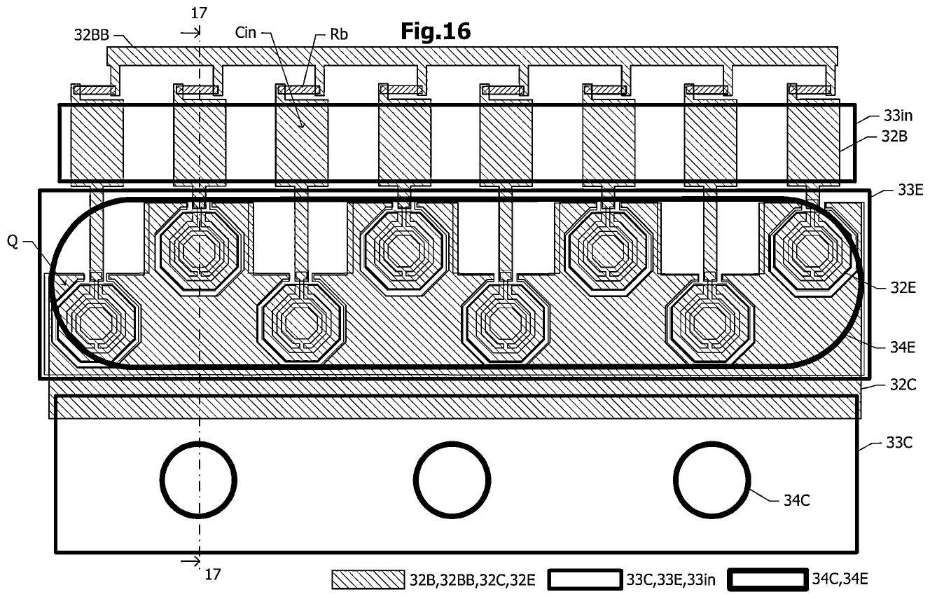

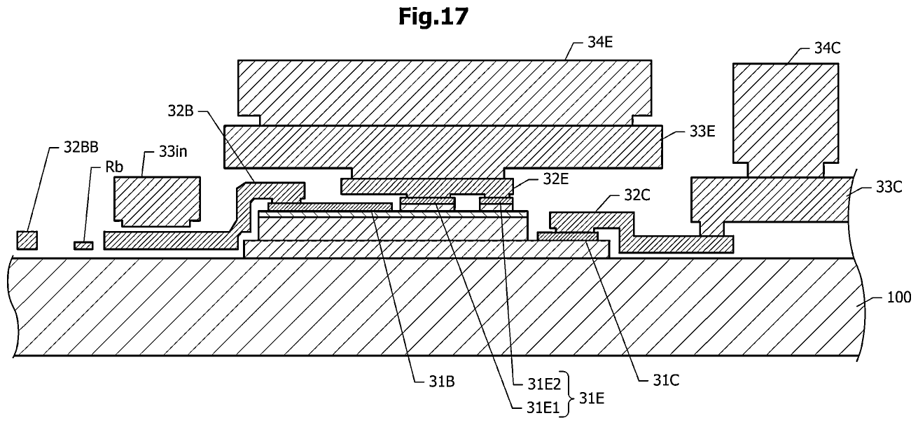

Next, a semiconductor device according to a third example is described with reference to FIGS. 16 and 17. Description of configurations in common with the semiconductor device (FIG. 12, FIG. 13, FIG. 14) according to the second example is omitted below. The semiconductor device according to the second example is face-up mounted on the module board, whereas the semiconductor device according to the third example is face-down mounted on the module board with a bump electrode being interposed therebetween.

FIG. 16 is a plan view illustrating a planar arrangement of respective components of the semiconductor device according to the third example. FIG. 17 is a sectional view taken along a one-dot chain line 17-17 in FIG. 16. In FIG. 16, wiring of the first layer is applied with hatching, wiring of the second layer is indicated by relatively thick outlines, and bump electrodes in a third layer are indicated by the thickest outlines.

Also in the semiconductor device according to the third example, similarly to the modification of the second example illustrated in FIG. 15, the multiple bipolar transistors Q are arranged in a staggered manner. Similarly to the second example (FIG. 13), the emitter wiring 33E of the second layer is disposed in such a manner as to overlap with the plurality of bipolar transistors Q in plan view. Furthermore, an emitter bump electrode 34E is disposed in such a manner as to overlap with the emitter wiring 33E of the second layer in plan view. The emitter bump electrode 34E is electrically connected to the emitter electrode 31E with the emitter wiring 33E of the second layer and the emitter wiring 32E of the first layer interposed therebetween.

On the opposite side from where the signal input wiring 33 in is disposed when seen from the emitter bump electrode 34E, the collector wiring 33C of the second layer is disposed. A part of the collector wiring 33C of the second layer overlaps with the collector wiring 32C of the first layer. The collector wiring 33C of the second layer is connected to the collector wiring 32C of the first layer at this overlapping range.

A plurality of collector bump electrodes 34C are disposed to be covered by the collector wiring 33C of the second layer in plan view. The collector bump electrode 34C is electrically connected to the collector electrode 31C with the collector wiring 33C of the second layer and the collector wiring 32C of the first layer interposed therebetween.

Next, beneficial effects of the third example are described.

As the bipolar transistor Q included in the semiconductor device according to the third example, the bipolar transistor according to the first example or the modification thereof is used. Therefore, the beneficial effect for improving the maximum oscillation frequency fmax of the semiconductor device is obtained. Moreover, the beneficial effects for increasing the SOA as described with reference to FIGS. 5A and 5B and suppressing occurrence of the current collapse as described with reference to FIG. 6 are obtained.

### Fourth Example

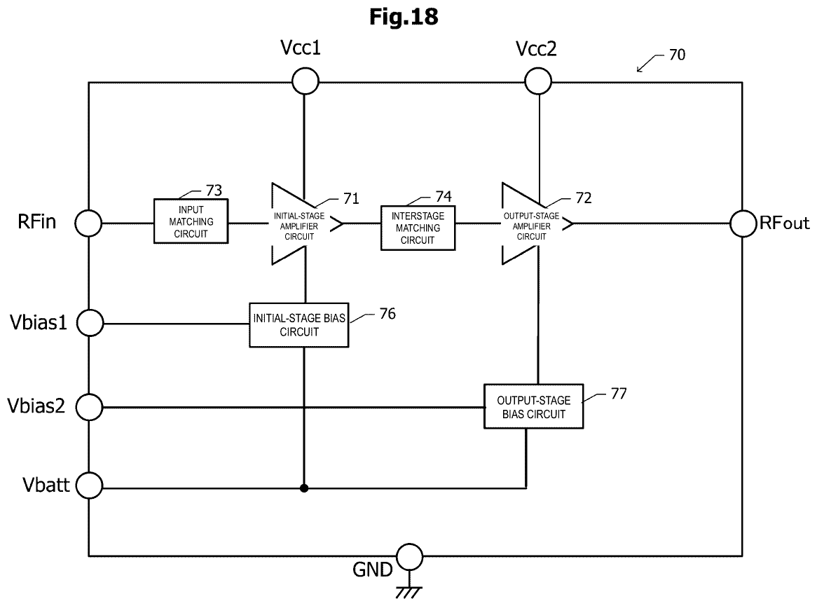

Next, a semiconductor device according to a fourth example is described with reference to FIGS. 18, 19, and 20. Description of configurations in common with the semiconductor device (FIG. 16, FIG. 17) according to the third example is omitted below. The semiconductor device according to the fourth example includes the semiconductor device (FIG. 16, FIG. 17) according to the third example.

FIG. 18 is a block diagram of a semiconductor device 70 according to the fourth example. The semiconductor device 70 according to the fourth example includes an initial-stage amplifier circuit 71, an output-stage amplifier circuit 72, an input matching circuit 73, an interstage matching circuit 74, an initial-stage bias circuit 76, and an output-stage bias circuit 77. Moreover, the semiconductor device 70 according to the fourth example includes, as an outer terminal constituted by a bump, a high-frequency signal input terminal RFin, a high-frequency signal output terminal RFout, an initial-stage bias control terminal Vbias1, an output-stage bias control terminal Vbias2, power supply terminals Vcc1 and Vcc2, a bias power supply terminal Vbatt, and a ground terminal GND. Note that although the block diagram in FIG. 18 illustrates only one ground terminal GND, the ground terminal GND includes a plurality of bumps in practice.

A high-frequency signal inputted from the high-frequency signal input terminal RFin is inputted into the initial-stage amplifier circuit 71 via the input matching circuit 73. The high-frequency signal amplified in the initial-stage amplifier circuit 71 is inputted into the output-stage amplifier circuit 72 via the interstage matching circuit 74. The high-frequency signal amplified in the output-stage amplifier circuit 72 is outputted from the high-frequency signal output terminal RFout. The bipolar transistor according to any of the first example and the modification thereof is used for the output-stage amplifier circuit 72.

The power supply terminals Vcc1 and Vcc2 respectively apply power voltage to the initial-stage amplifier circuit 71 and the output-stage amplifier circuit 72. The bias power supply terminal Vbatt supplies bias power supply to the initial-stage bias circuit 76 and the output-stage bias circuit 77. The initial-stage bias circuit 76 supplies bias to the initial-stage amplifier circuit 71 based on a bias control signal inputted into the initial-stage bias control terminal Vbias1. The output-stage bias circuit 77 supplies bias to the output-stage amplifier circuit 72 based on a bias control signal inputted into the output-stage bias control terminal Vbias2.

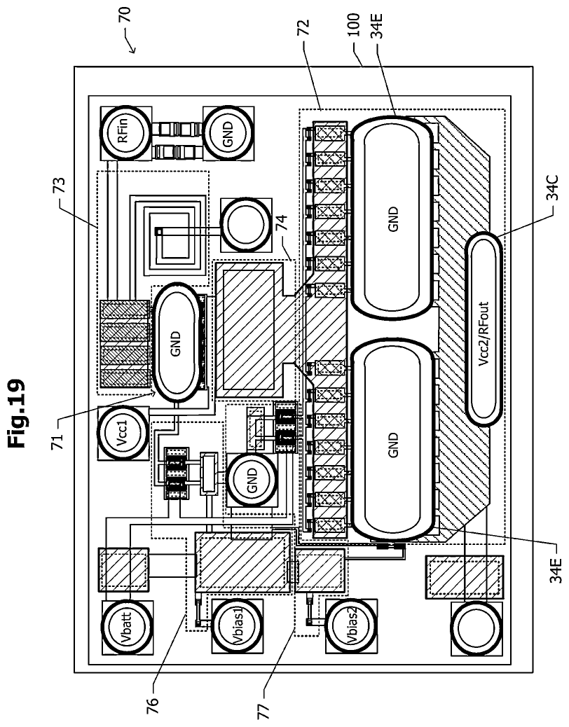

FIG. 19 is a view illustrating arrangement of respective components in a substrate of the semiconductor device 70 according to the fourth example. In FIG. 19, hatching is applied to substantial wiring of the first layer and the second layer.

The output-stage amplifier circuit 72 makes up approximately 40% of an upper surface of the substrate 100. Although in the third example (FIG. 16) one emitter bump electrode 34E is disposed for eight bipolar transistors Q, in the fourth example, fourteen bipolar transistors Q are divided into two sets, and the emitter bump electrode 34E is disposed for each of two sets. Moreover, although in the third example (FIG. 16) three collector bump electrodes 34C are disposed for eight bipolar transistors Q, in the fourth example, one collector bump electrode 34C is disposed for fourteen bipolar transistors Q. The collector bump electrode 34C corresponds to the power supply terminal Vcc2 (FIG. 18) and the high-frequency signal output terminal RFout.

On the upper surface of the substrate 100, additionally, the initial-stage amplifier circuit 71, the input matching circuit 73, the interstage matching circuit 74, the initial-stage bias circuit 76, the output-stage bias circuit 77, the high-frequency signal input terminal RFin, the power supply terminal Vcc1, the bias power supply terminal Vbatt, the initial-stage bias control terminal Vbias1, and the output-stage bias control terminal Vbias2 are disposed. Furthermore, for example, the ground terminal GND connected to emitters of a plurality of bipolar transistors included in the initial-stage amplifier circuit 71 are disposed.

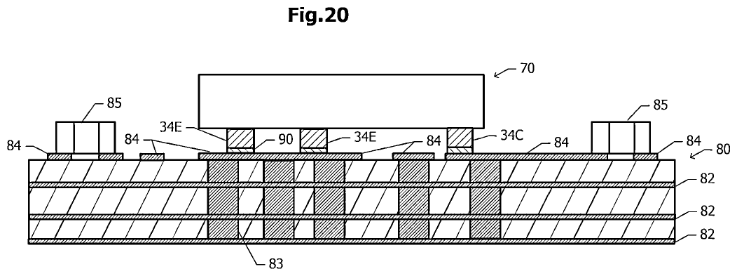

FIG. 20 is a schematic sectional view in a state in which the semiconductor device 70 according to the fourth example is mounted on a module board 80. On one surface of the semiconductor device 70, the emitter bump electrode 34E, the collector bump electrode 34C, and the like are disposed. A plurality of lands 84 are disposed on a mounting surface of the module board 80. The emitter bump electrode 34E of the semiconductor device 70 is connected by solder 90 to the land 84 for grounding of the module board 80.

Note that, in addition to the emitter bump electrode 34E and the collector bump electrode 34C, a plurality of bump electrodes (FIG. 19) for power supply and signals are provided to the semiconductor device 70. These bump electrodes are also connected by solder to the corresponding lands of the module board 80.

In addition to the semiconductor device 70, a plurality of surface mount devices 85, such as an inductor and a capacitor, are mounted on the mounting surface of the module board 80. A ground plane 82 is provided to the module board 80 at an inner layer and a surface (hereinafter, referred to as a back surface) opposite from the mounting surface. Multiple vias 83 are provided from the lands 84 for grounding disposed on the mounting surface to reach the ground plane 82 on the back surface.

Next, beneficial effects of the fourth example are described.

In the fourth example, one semiconductor chip forms the two-stage amplifier circuit. Since the bipolar transistor according to the first example or the modification thereof is used for the output-stage amplifier circuit 72, a maximum oscillation frequency fmax can be improved. Moreover, the beneficial effects for increasing the SOA as described with reference to FIGS. 5A and 5B and suppressing occurrence of the current collapse as described with reference to FIG. 6 are obtained.

Each example described above is merely illustrations, and needless to say, partial replacement or combination of the configurations presented in the different examples is possible. Similar operation and effects attributed to the similar configurations in the plurality of examples are not mentioned one by one in each example. Furthermore, the present disclosure is not limited to the examples described above. For example, it is obvious to the person skilled in the art that various changes, improvements, combinations, and the like are possible.

What is claimed is:

1. A bipolar transistor comprising:
a substrate;
a mesa structure including a collector layer, a base layer, and an emitter layer laminated on the substrate;
an emitter electrode on the mesa structure and electrically connected to the emitter layer;
a base electrode on the mesa structure and electrically connected to the base layer; and
a collector electrode surrounding the mesa structure in plan view, and electrically connected to the collector layer, wherein
the emitter electrode includes a first part and a second part, and
in plan view, the base electrode surrounds the first part of the emitter electrode, and the second part of the emitter electrode surrounds the base electrode.

2. The bipolar transistor according to claim 1, further comprising:
an interlayer dielectric on the substrate to cover the collector electrode, the emitter electrode, and the base electrode; and
emitter wiring on the interlayer dielectric, and connected to the first part and the second part of the emitter electrode while passing through a cavity of the interlayer dielectric, wherein
a shape of the emitter wiring in plan view has two line-symmetric axes orthogonal to one another, and among dimensions of the shape of emitter wiring in a direction of one of the line-symmetric axes and in a direction of another one of the line-symmetric axes, a larger dimension is 1.2 times or less a smaller dimension.

3. The bipolar transistor according to claim 1, wherein
the base electrode surrounds the first part of the emitter electrode continuously without a gap in plan view.

4. The bipolar transistor according to claim 1, wherein
the second part of the emitter electrode surrounds the base electrode continuously without a gap in plan view.

5. The bipolar transistor according to claim 1, wherein
a part of the second part of the emitter electrode has a gap, and
the bipolar transistor further includes a base electrode extended part continuing to the base electrode and extended to an outer side of the second part of the emitter electrode while passing through the gap of the second part.

6. The bipolar transistor according to claim 1, wherein
the first part of the emitter electrode has a regular hexagonal shape, a regular octagonal shape, a rounded regular hexagonal shape, or a rounded regular octagonal shape in plan view.

7. The bipolar transistor according to claim 1, wherein
the collector layer, the base layer, and the emitter layer include compound semiconductors.

8. A semiconductor device comprising:
a plurality of the bipolar transistors according to claim 1, wherein
the plurality of bipolar transistors are on the substrate in common, in a staggered manner in plan view, and connected in parallel to one another.

9. A semiconductor device comprising:
a plurality of the bipolar transistors according to claim 1, wherein
the plurality of bipolar transistors are on the substrate in common,
the semiconductor device further includes a back electrode on a surface of the substrate, the surface being an opposite side from a surface where the mesa structure is present,
the substrate includes a via hole penetrating the substrate, and
the back electrode is electrically connected to the emitter electrode through the via hole.

10. The semiconductor device according to claim 9, further comprising:
a bonding pad connected to the collector electrode.

11. A semiconductor device comprising:
a plurality of the bipolar transistors according to claim 1, wherein
the plurality of bipolar transistors are on the substrate in common, and
the semiconductor device further includes an emitter bump electrode on the substrate and electrically connected to the emitter electrode.

12. The bipolar transistor according to claim 2, wherein
the base electrode surrounds the first part of the emitter electrode continuously without a gap in plan view.

13. The bipolar transistor according to claim 2, wherein
the second part of the emitter electrode surrounds the base electrode continuously without a gap in plan view.

14. The bipolar transistor according to claim 2, wherein
a part of the second part of the emitter electrode has a gap, and
the bipolar transistor further includes a base electrode extended part continuing to the base electrode and extended to an outer side of the second part of the emitter electrode while passing through the gap of the second part.

15. The bipolar transistor according to claim 2, wherein
the first part of the emitter electrode has a regular hexagonal shape, a regular octagonal shape, a rounded regular hexagonal shape, or a rounded regular octagonal shape in plan view.

16. The bipolar transistor according to claim 2, wherein
the collector layer, the base layer, and the emitter layer include compound semiconductors.

17. A semiconductor device comprising:
a plurality of the bipolar transistors according to claim 2, wherein
the plurality of bipolar transistors are on the substrate in common, in a staggered manner in plan view, and connected in parallel to one another.

18. A semiconductor device comprising:
a plurality of the bipolar transistors according to claim 2, wherein
the plurality of bipolar transistors are on the substrate in common,
the semiconductor device further includes a back electrode on a surface of the substrate, the surface being an opposite side from a surface where the mesa structure is present,
the substrate includes a via hole penetrating the substrate, and
the back electrode is electrically connected to the emitter electrode through the via hole.

19. The semiconductor device according to claim 18, further comprising:
a bonding pad connected to the collector electrode.

20. A semiconductor device comprising:
a plurality of the bipolar transistors according to claim 2, wherein
the plurality of bipolar transistors are on the substrate in common, and
the semiconductor device further includes an emitter bump electrode on the substrate and electrically connected to the emitter electrode.
